(19) United States
(12) Patent Application Publication
(10) Pub. No.: US 2024/0403516 A1
(43) Pub. Date: Dec. 5, 2024

(54) SIMULATION LAYER SELECTION DEVICE, SIMULATION LAYER SELECTION METHOD, AND SIMULATION LAYER SELECTION PROGRAM

(71) Applicant: NIPPON TELEGRAPH AND TELEPHONE CORPORATION, Tokyo (JP)

(72) Inventors: Atsushi ISOMURA, Musashino-shi, Tokyo (JP); Yasuhiro IIDA, Musashino-shi, Tokyo (JP); Kazuhiro YOSHIDA, Musashino-shi, Tokyo (JP)

(73) Assignee: NIPPON TELEGRAPH AND TELEPHONE CORPORATION, Tokyo (JP)

(21) Appl. No.: 18/697,734

(22) PCT Filed: Oct. 5, 2021
(86) PCT No.: PCT/JP2021/036873

§ 371 Date: Apr. 2, 2024

(51) Int. Cl. G06F 30/20

(52) U.S. Cl. CPC G06F 30/20

(57) ABSTRACT

An acquisition unit acquires a search word indicating a requirement for simulation. A calculation unit calculates, for each of a plurality of simulation layers capable of constituting the simulation, a simulation result in the simulation layer corresponding to each of patterns of two or more predetermined parameters and a difference between the simulation results. A selection unit selects a predetermined number of the simulation layers in descending order of a maximum value among differences between the simulation results in each simulation layer.

### TECHNICAL FIELD

The present invention relates to a simulation layer selection device, a simulation layer selection method, and a simulation layer selection program.

### BACKGROUND ART

In recent years, technology called a digital twin in which an environment of a real space is reproduced in a digital virtual space to perform analysis and prediction has been anticipated. In addition, a technique for performing a highly accurate simulation using a digital twin is known (refer to NPL 1).

### CITATION LIST

### Non Patent Literature

[NPL 1] “For the realization of a future society in which harmonious relationships between the earth, society, and individuals are established, ˜Four challenges of digital twin computing˜,” [online], November 2020, NTT, [retrieved on Sep. 14, 2021], Internet <URL:https://group.ntt/jp/newsrelease/2020/11/13/201113c.html>

### SUMMARY OF INVENTION

### Technical Problem

According to the related art, it was not possible to select which layer is to be used from among a plurality of simulation layers for information and services desired by a user.

The present invention has been made in view of the above, and an object of the present invention is to make it possible to easily select which layer is to be used from among a plurality of simulation layers for information and services desired by a user.

### Solution to Problem

In order to solve the above-described problems and achieve the object, a simulation layer selection device according to the present invention includes: an acquisition unit configured to acquire a search word indicating a requirement for simulation; a calculation unit configured to calculate, for each of a plurality of simulation layers capable of constituting the simulation, a simulation result in the simulation layer corresponding to each of patterns of two or more predetermined parameters and a difference between the simulation results; and a selection unit configured to select a predetermined number of the simulation layers in descending order of a maximum value among differences between the simulation results in each simulation layer.

### Advantageous Effects of Invention

According to the present invention, it is possible to easily select which layer is to be used from among a plurality of simulation layers for information and services desired by a user.

### BRIEF DESCRIPTION OF DRAWINGS

FIG. 1 is a diagram for describing an outline of a simulation layer selection device according to the present embodiment.

FIG. 2 is a schematic diagram illustrating a schematic configuration of the simulation layer selection device according to the present embodiment.

FIG. 3 is a diagram for describing processing of an acquisition unit.

FIG. 4 is a diagram for describing processing of a presentation unit.

FIG. 5 is a diagram for describing processing of the presentation unit.

FIG. 6 is a diagram for describing processing of an execution unit.

FIG. 7 is a diagram for describing processing of the execution unit.

FIG. 8 is a flowchart illustrating a simulation layer selection processing procedure.

FIG. 9 is a diagram for describing the effects of the simulation layer selection processing.

FIG. 10 is a diagram illustrating an example of a computer that executes a simulation layer selection program.

### DESCRIPTION OF EMBODIMENTS

An embodiment of the present invention will be described in detail below with reference to the drawings. The present invention is not limited to the present embodiment. Further, in the description of the drawings, the same parts are denoted by the same reference signs.

### Outline of Simulation Layer Selection Device

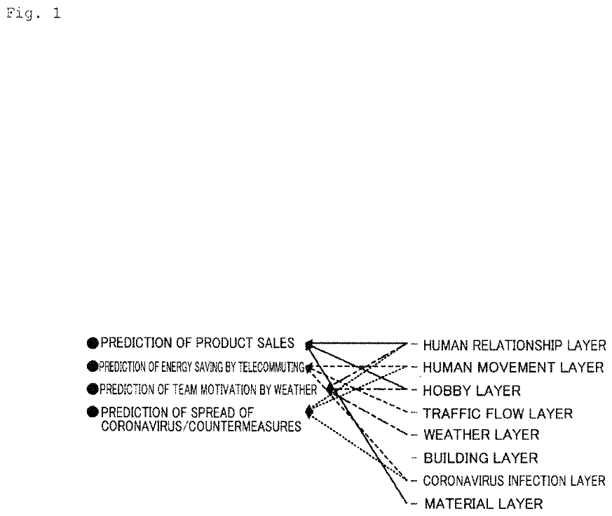

FIG. 1 is a diagram for describing an outline of a simulation layer selection device according to the present embodiment. The simulation layer selection device according to the present embodiment selects an optimum simulation layer from a plurality of simulation layers in order to execute multi-layer simulation implemented by a combination of a plurality of simulation layers.

For example, as illustrated in FIG. 1, the simulation layer selection device estimates and selects a simulation layer optimum for constructing multi-layer simulation that implements a service by using a search word input for designating requirements for the service desired by a user. In the example illustrated in FIG. 1, for example, in a case where “prediction of product sales” is input as a search word, multi-simulation for predicting product sales is estimated to be implemented by a combination of the human relationship layer, the hobby layer, and the material layer, and is selected. Therefore, in a case where the requirements for a desired simulation are designated, it becomes possible to easily construct simulation without constructing simulation from scratch.

### Configuration of Simulation Layer Selection Device

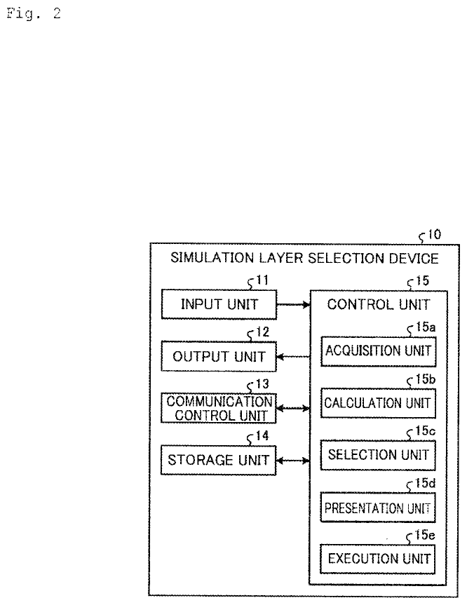

FIG. 2 is a schematic diagram illustrating a schematic configuration of the simulation layer selection device according to the present embodiment. As illustrated in FIG. 2, a simulation layer selection device 10 according to the present embodiment is implemented as a general-purpose computer such as a personal computer and includes an input unit 11, an output unit 12, a communication control unit 13, a storage unit 14, and a control unit 15.

The input unit 11 is implemented by using an input device such as a keyboard or a mouse and receives various types of instruction information such as for the control unit 15 to start processing in response to an input operation from an operator. The output unit 12 is implemented by a display device such as a liquid crystal display, a printer, or the like. For example, the output unit 12 displays results of simulation layer selection processing, which will be described later.

The communication control unit 13 is implemented by a network interface card (NIC) or the like and controls communication between an external device and the control unit 15 via a telecommunication line such as a local area network (LAN) or the Internet. For example, the communication control unit 13 controls communication between the control unit 15 and a user terminal or the like of a user who uses simulation layer selection processing, which will be described later.

The storage unit 14 is implemented by a semiconductor memory element such as a random access memory (RAM) or a flash memory, or a storage device such as a hard disk or an optical disc. The storage unit 14 stores in advance a processing program for operating the simulation layer selection device 10, data used during execution of the processing program, and the like, or temporarily performs storing each time the processing is performed. Note that the storage unit 14 may also be configured to communicate with the control unit 15 via the communication control unit 13.

In the present embodiment, the storage unit 14 stores models of each simulation layer used in simulation layer selection processing to be described later, patterns of predetermined parameters of each simulation layer, and the like. As patterns of predetermined parameters, for example, patterns of two or more predetermined parameters are stored for each simulation layer, such as four pattern parameters of sunny, cloudy, rainy, and snowy for the weather simulation layer.

The control unit 15 is implemented by using a central processing unit (CPU) or the like and executes a processing program stored in a memory. Accordingly, the control unit 15 functions as an acquisition unit 15a, a calculation unit 15b, a selection unit 15c, a presentation unit 15d, and an execution unit 15e as illustrated in FIG. 2.

Note that each or some of these functional units may be implemented in different hardware. For example, the presentation unit 15d and the execution unit 15e may be implemented in a device different from other functional units. Further, the control unit 15 may include another functional unit.

The acquisition unit 15a acquires a search word indicating requirements for simulation. Specifically, the acquisition unit 15a receives the input of a search word indicating the requirements for simulation desired by the user via the input unit 11 or the communication control unit 13 from another device such as a user terminal. The acquisition unit 15a may store the acquired search word in the storage unit 14, or may immediately transfer the search word to the calculation unit 15b to be described later without storing the search word in the storage unit 14.

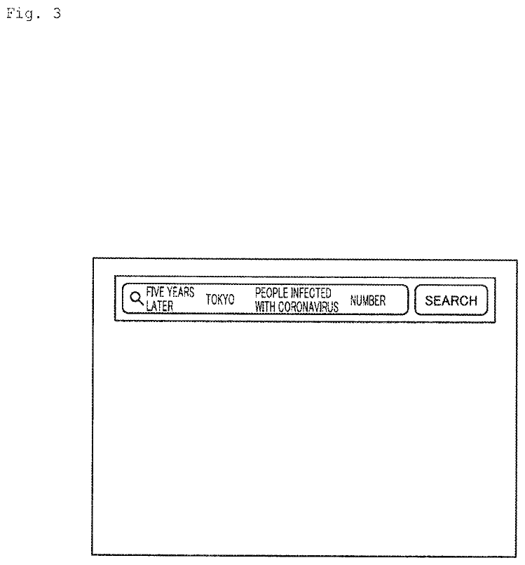

Here, FIG. 3 is a diagram for describing processing of the acquisition unit. The acquisition unit 15a acquires a search word input by the user, for example, as illustrated in FIG. 3. In the example illustrated in FIG. 3, the user has entered “five years later/Tokyo/people infected with coronavirus/number” as a search word for designating a desired multi-layer simulation.

The description will now return to FIG. 2. The calculation unit 15b calculates a simulation result in the simulation layer corresponding to each of patterns of two or more predetermined parameters and a difference between the simulation results for each of a plurality of simulation layers capable of constituting the simulation. Specifically, the calculation unit 15b calculates the difference between the simulation results in the part represented by the number included in the search word in the simulation results. For example, the calculation unit 15b first extracts a number part represented by a number such as “number of people”, “profit rate”, “number of sales”, and the like included in the search word.

The calculation unit 15b applies patterns of two or more preset parameters to each simulation layer to calculate a simulation result corresponding to each pattern. For example, patterns of three parameters of preset patterns A, B, and C are applied to a certain simulation layer to calculate a simulation result in the simulation layer. That is, the calculation unit 15b calculates a simulation result A in a case where the parameter of the pattern A is applied, a simulation result B in a case where the parameter of the pattern B is applied, and a simulation result C in a case where the parameter of the pattern C is applied.

Next, the calculation unit 15b calculates the difference between the simulation results A, B, and C. In this case, the calculation unit 15b calculates the difference between number parts of each simulation result. For example, in a case where the search word is “OO/number of sales”, the simulation result indicates, for example, the “number of sales of OO”. In this case, the number part of the search word is the “number of sales”, and the calculation unit 15b calculates the difference between the numbers of sales of the simulation results A, B, and C. In a case where the simulation result of a certain simulation layer does not explicitly indicate the number of sales, the difference in the number of sales is 0.

The calculation unit 15b calculates the maximum value among the differences between the calculated simulation results A, B, and C, and stores the difference between the simulation results of the simulation layer in the storage unit 14. For example, in a case where the simulation result A is 5, the simulation result B is 10, and the simulation result C is 40, the calculation unit 15b stores the maximum value of the differences=40−5=35 as the difference between the simulation results of the simulation layer. The calculation unit 15b performs the above processing for each simulation layer.

The selection unit 15c selects a predetermined number L of simulation layers in descending order of the maximum value among the differences between the simulation results in each simulation layer. Here, it is considered that the larger the maximum value, the larger the influence on the multi-simulation. Therefore, for example, when the predetermined number L=2 and the maximum values of the differences between the simulation results of simulation layers α, β, and γ calculated by the calculation unit 15b are 10, 6, and 2, the selection unit 15c selects the simulation layers α and β.

The predetermined number L is set to a large value in accordance with complexity of multi-layer simulation that implements a desired service, for example. That is, the value of L becomes smaller as the simple multi-layer simulation is performed, and the value of L becomes larger as the complicated multi-layer simulation is performed. The value of L may be set in advance and stored in the storage unit 14, or may be input by a user, an operator, or the like in the simulation layer selection processing.

The selection unit 15c selects a predetermined number of simulation layers in descending order of the maximum value among the differences calculated in each simulation layer for each of parts represented by a plurality of numbers included in the search word. In other words, the selection unit 15c executes processing for selecting a simulation layer for each of a plurality of number parts represented by the numbers included in the search word. For example, in a case where a plurality of number parts such as “number of sales” and “number of people” are included in the search word, the calculation unit 15b and the selection unit 15c first perform the above processing on the “number of sales” and select L simulation layers constructing multi-layer simulation for the “number of sales”. Also, the calculation unit 15b and the selection unit 15c perform similar processing on the “number of people” to select L simulation layers.

A different L may be applied to each of number parts. For example, the simulation layer selection device 10 may explicitly indicate a plurality of number parts extracted from the search word to the user, and receive designation of the value of L for each part.

The presentation unit 15d presents the selected simulation layer. That is, the presentation unit 15d outputs the result of the simulation layer selection processing to an external device such as a user terminal via the output unit 12 or the communication control unit 13.

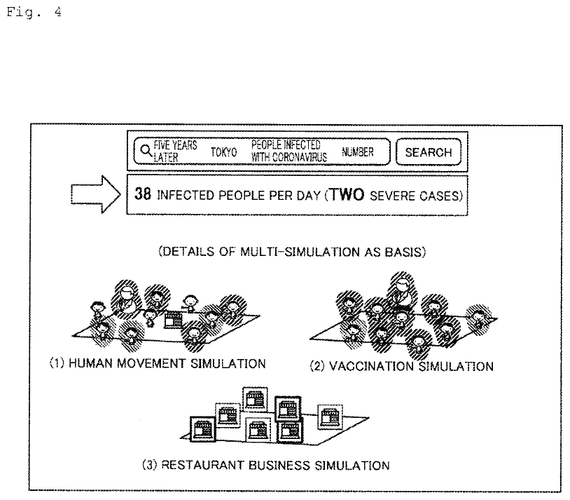

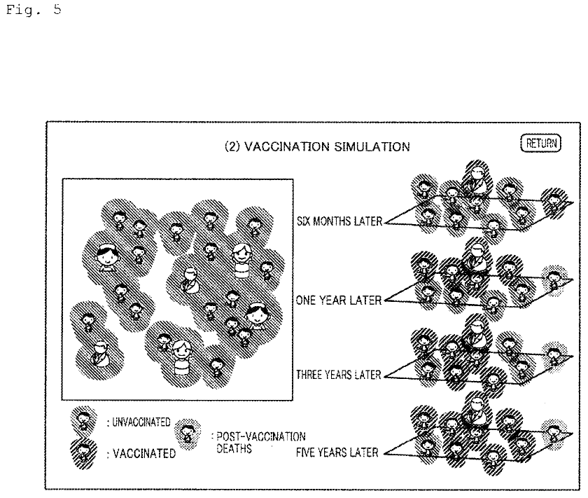

Here, FIGS. 4 and 5 are diagrams for describing processing of the presentation unit. As illustrated in FIG. 4, the presentation unit 15d presents the result of the above simulation layer selection processing to the user. In the example illustrated in FIG. 4, a human movement simulation layer, a vaccination simulation layer, and a restaurant business simulation layer are selected for the multi-layer simulation showing “five years later/Tokyo/people infected with coronavirus/number”. The simulation layer selected here is a simulation layer which has a large influence on the multi-layer simulation and is necessary as a component.

In addition, in the example illustrated in FIG. 4, the result of the multi-layer simulation with “38 infected people per day (two severe cases)” is presented. In FIG. 4, for example, when the vaccination simulation layer is designated, as illustrated in FIG. 5, processing content of the vaccination simulation layer is presented. In the example illustrated in FIG. 5, the vaccination simulation layer reproduces the status of unvaccinated people, vaccinated people, and post-vaccination deaths after six months, one year, three years, and five years.

The description will now return to FIG. 2. The execution unit 15e receives the change of the parameter for the presented simulation layer and executes simulation. For example, the execution unit 15e executes “What-If analysis” in which assumption conditions are set by changing parameters for each of the selected and presented simulation layers and simulation is performed.

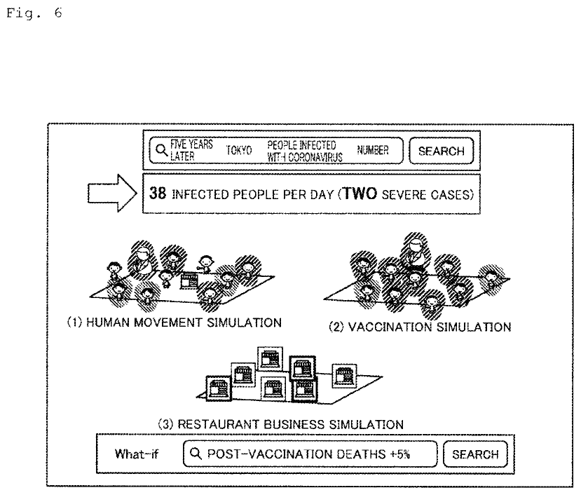

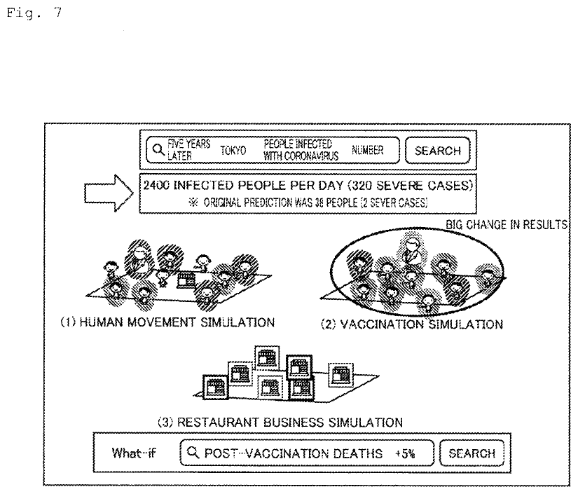

Here, FIGS. 6 and 7 are diagrams for describing processing of the execution unit. In the example illustrated in FIG. 6, What-If analysis is executed on the vaccination simulation layer with “post-vaccination deaths ±58”. In addition, as a result, in the example illustrated in FIG. 7, the result of the multi-layer simulation with “2400 infected people per day (320 severe cases)” is presented. This result greatly changes as compared to the results of “38 infected people per day (two severe cases)” illustrated in FIG. 4. In this way, the simulation layer selection device 10 can easily execute What-If analysis on multi-layer simulations.

### Simulation Layer Selection Processing

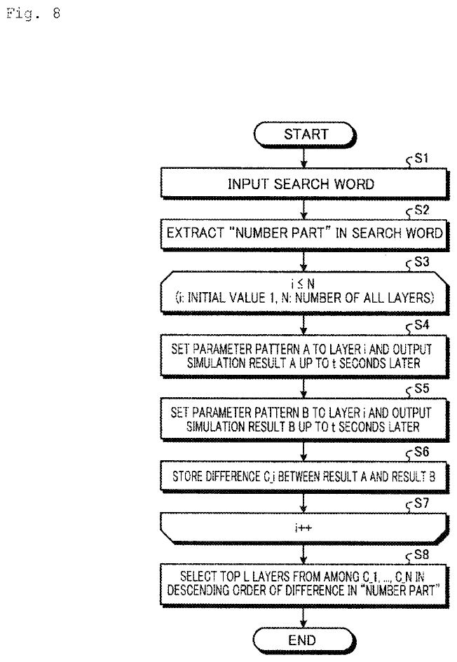

Next, simulation layer selection processing by the simulation layer selection device 10 according to the present embodiment will be described with reference to FIG. 8. FIG. 8 is a flowchart illustrating a simulation layer selection processing procedure. The flowchart of FIG. 8 is started, for example, at the timing at which the user inputs an operation instructing the start.

First, the acquisition unit 15a receives the input of a search word representing the requirements for simulation desired by a user (step S1).

Next, the calculation unit 15b extracts a part represented by the number included in the search word (step S2).

The calculation unit 15b applies patterns of two or more predetermined parameters to an i-th (1≤+i≤N) simulation layer (step S3) to calculate a simulation result corresponding to each pattern (steps S4 and S5). For example, patterns of two parameters of preset patterns A and B are applied to the i-th simulation layer to calculate a simulation result in the simulation layer. That is, the calculation unit 15b calculates a simulation result A in a case where the parameter of the pattern A is applied, and a simulation result B in a case where the parameter of the pattern B is applied.

The calculation unit 15b also calculates the maximum value of the difference between the simulation results (step S6). For example, the calculation unit 15b calculates a difference C_i between the simulation results A and B and stores it in the storage unit 14. Then, the calculation unit 15b repeats the processing of steps S4 to S6 for the (i+1)-th simulation layer (step S7→step S3).

The calculation unit 15b advances the processing to step S8 in the case of calculating the maximum value of the difference between simulation results in the simulation layers corresponding to each of the patterns of two or more predetermined parameters for all the simulation layers.

In the processing of step S8, the selection unit 15c selects a predetermined number L of simulation layers in descending order of the maximum value among differences between simulation results in each simulation layer, that is, in descending order of influence. Thus, a series of simulation layer selection processing ends.

### Effects

As described above, in the simulation layer selection device 10 according to the present embodiment, the acquisition unit 15a acquires search words representing the requirements for simulation. The calculation unit 15b calculates a simulation result in the simulation layer corresponding to each of patterns of two or more predetermined parameters and a difference between the simulation results for each of a plurality of simulation layers capable of constituting the simulation. The selection unit 15c selects a predetermined number of simulation layers in descending order of the maximum value among the differences between the simulation results in each simulation layer.

Specifically, the calculation unit 15b calculates the difference between the simulation results in the part represented by the number included in the search word in the simulation results.

In this way, the simulation layer selection device 10 estimates and selects a simulation layer having a large influence of parameter change as a simulation layer essential to the construction of the multi-layer simulation. Thus, the simulation layer selection device 10 can easily select which layer is to be used from among a plurality of existing simulation layers for information and services desired by a user. Therefore, it is possible to easily implement simulation for satisfying a plurality of different requirements such as “prediction of the number of coronavirus cases per day in several years”, “prediction of evacuation route congestion due to heavy rain after three days”, or the like in a single system.

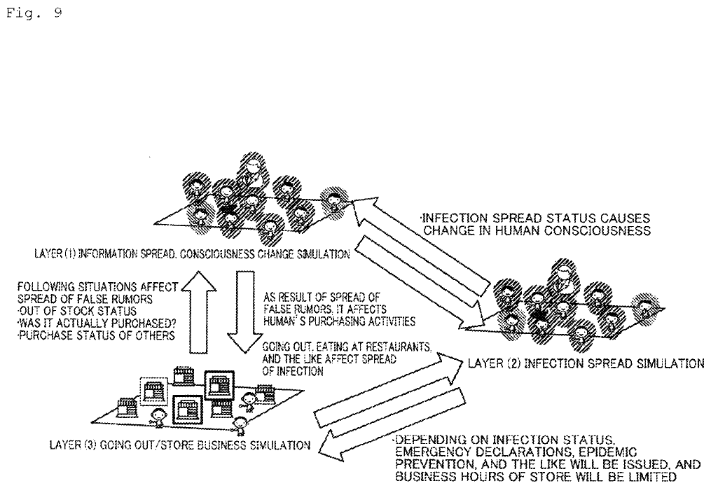

Here, FIG. 9 is a diagram for describing the effects of the simulation layer selection processing. The multi-layer simulation is implemented by a combination of a plurality of simulation layers. In that case, as illustrated in FIG. 9, the simulation of each simulation layer requires reproduction of each person. On the other hand, it is necessary to consider the influence of the simulation results of the other simulation layers for the simulation results of each simulation layer.

For such a multi-layer simulation, What-If analysis in which assumption conditions are set for each simulation layer selected by the simulation layer device and simulation is performed is possible. Therefore, for example, what-If analysis can be performed on the multi-layer simulation that reproduces the situation of becoming accustomed to the coronavirus illustrated in FIG. 9, and it is possible to clarify the optimal measures for the spread of preventive measures such as self-restraint of store business.

In addition, the selection unit 15c selects a predetermined number of the simulation layers in descending order of the maximum value among the differences calculated in each simulation layer for each of parts represented by a plurality of numbers included in the search word. Thus, the multi-layer simulation with higher accuracy can be constructed.

Also, the presentation unit 15d presents the selected simulation layer. This improves convenience for the user, and facilitates analysis such as What-If analysis, for example.

Also, the execution unit 15e receives the change of the parameter for the presented simulation layer and executes simulation. Thus, analysis such as What-If analysis can be performed.

### Program

A program in which the processing executed by the simulation layer selection device 10 according to the above embodiment is described in a computer-executable language can also be created. As an embodiment, the simulation layer selection device 10 can be implemented by installing a simulation layer selection program for executing the above simulation layer selection processing as packaged software or online software in a desired computer. For example, the information processing device can function as the simulation layer selection device 10 by causing the information processing device to execute the above simulation layer selection program. The information processing device mentioned here includes a desktop or laptop personal computer. Further, a mobile communication terminal such as a smartphone, a mobile phone, or a personal handyphone system (PHS), or a slate terminal such as a personal digital assistant (PDA), for example, is included in a category of the information processing device. Furthermore, the functions of the simulation layer selection device 10 may be implemented in a cloud server.

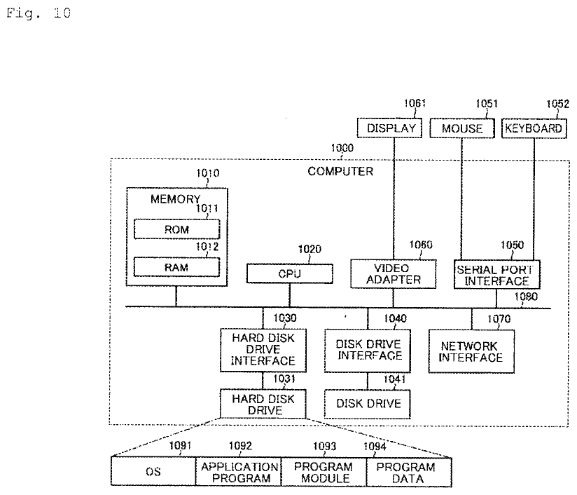

FIG. 10 is a diagram illustrating an example of a computer that executes a simulation layer selection program. A computer 1000 includes, for example, a memory 1010, a CPU 1020, a hard disk drive interface 1030, a disk drive interface 1040, a serial port interface 1050, a video adapter 1060, and a network interface 1070. These units are connected by a bus 1080.

The memory 1010 includes a read only memory (ROM) 1011 and a RAM 1012. The ROM 1011 stores, for example, a boot program, such as a basic input output system (BIOS). The hard disk drive interface 1030 is connected to a hard disk drive 1031. The disk drive interface 1040 is connected to a disk drive 1041. A detachable storage medium such as a magnetic disk or an optical disc, for example, is inserted into the disk drive 1041. A mouse 1051 and a keyboard 1052, for example, are connected to the serial port interface 1050. A display 1061, for example, is connected to the video adapter 1060.

Here, the hard disk drive 1031 stores, for example, an OS 1091, an application program 1092, a program module 1093, and program data 1094. Each of the pieces of information described in the above embodiment is stored in, for example, the hard disk drive 1031 or the memory 1010.

For example, the simulation layer selection program is stored in the hard disk drive 1031 as the program module 1093 in which instructions executed by the computer 1000 are described. Specifically, the program module 1093 in which each piece of processing executed by the simulation layer selection device 10 described in the above embodiment is described is stored in the hard disk drive 1031.

Data used for information processing by the simulation layer selection program is stored in, for example, the hard disk drive 1031 as the program data 1094. Then, the CPU 1020 reads the program module 1093 and the program data 1094 stored in the hard disk drive 1031 to the RAM 1012 as necessary, and executes each of the above-described procedures.

Note that the program module 1093 and the program data 1094 related to the simulation layer selection program are not limited to being stored in the hard disk drive 1031, and may be stored in, for example, a detachable storage medium and read by the CPU 1020 via the disk drive 1041 or the like. Alternatively, the program module 1093 and the program data 1094 related to the simulation layer selection program may be stored in another computer connected via a network such as a LAN or a wide area network (WAN) and read by the CPU 1020 via the network interface 1070.

Although the embodiments to which the invention made by the present inventors is applied have been described above, the present invention is not limited by the description and the drawings forming a part of the disclosure of the present invention according to the present embodiments. In other words, other embodiments, examples, operational technologies, and the like made by those skilled in the art and the like on the basis of the present embodiment are all included in the scope of the present invention.

### REFERENCE SIGNS LIST

10 Simulation layer selection device
11 Input unit
12 Output unit
13 Communication control unit
14 Storage unit
15 Control unit
15a Acquisition unit
15b Calculation unit
15c Selection unit
15d Presentation unit
15e Execution unit

1. A simulation layer selection device, comprising:
acquisition circuitry configured to acquire a search word indicating a requirement for simulation;
calculation circuitry configured to calculate, for each of a plurality of simulation layers capable of constituting the simulation, a simulation result in the simulation layer corresponding to each of patterns of two or more predetermined parameters and a difference between the simulation results; and
selection circuitry configured to select a predetermined number of the simulation layers in descending order of a maximum value among differences between the simulation results in each simulation layer.

2. The simulation layer selection device according to claim 1, wherein:
the calculation circuitry calculates a difference between the simulation results in a part represented by a number included in the search word in the simulation results.

3. The simulation layer selection device according to claim 2, wherein:
the selection circuitry selects a predetermined number of the simulation layers in descending order of the maximum value among the differences calculated in each simulation layer for each of parts represented by a plurality of numbers included in the search word.

4. The simulation layer selection device according to claim 1, further comprising:
a display to present the selected simulation layer.

5. The simulation layer selection device according to claim 4, further comprising:
an execution circuitry configured to receive a change in a parameter for the presented simulation layer and execute the simulation.

6. A simulation layer selection method, comprising:
acquiring a search word indicating a requirement for simulation;
calculating, for each of a plurality of simulation layers capable of constituting the simulation, a simulation result in the simulation layer corresponding to each of patterns of two or more predetermined parameters and a difference between the simulation results; and
selecting a predetermined number of the simulation layers in descending order of a maximum value among differences between the simulation results in each simulation layer.

7. A non-transitory computer readable medium storing a simulation layer selection program for causing a computer to perform the method of claim 6.
